(19) United States
(12) Patent Application Publication
(10) Pub. No.: US 2025/0351558 A1
(43) Pub. Date: Nov. 13, 2025

(54) SEMICONDUCTOR DEVICE WITH GATE STRAP IN STI REGION

(71) Applicant: INTERNATIONAL BUSINESS MACHINES CORPORATION, ARMONK, NY (US)

(72) Inventors: Ruilong Xie, Niskayuna, NY (US); James P. Mazza, Saratoga Springs, NY (US); Shay Reboh, Guilderland, NY (US); Chen Zhang, Santa Clara, CA (US)

(21) Appl. No.: 18/661,607

(22) Filed: May 11, 2024

(51) Int. Cl. H01L 27/088; H01L 29/06; H01L 29/417; H01L 29/423; H01L 29/775; H01L 29/786

(52) U.S. Cl. CPC H10D 84/83; H10D 30/43; H10D 30/6735; H10D 30/6757; H10D 62/121; H10D 64/258; H10D 64/518

(57) ABSTRACT

In an attempt to reduce congestion in the upper layers and improve efficiency in semiconductor devices, embodiments comprise a semiconductor device that comprises a substrate, a shallow trench isolation (STI) layer formed on the substrate. The semiconductor device also includes comprises a first gate, a second gate, and a gate strap connecting the first gate to the second gate. The gate strap is formed in the STI layer.

### BACKGROUND

The present disclosure relates to fabrication methods and resulting structures for semiconductor devices. More specifically, the present disclosure relates to fabrication methods and resulting structures for semiconductor devices including a gate strap structure for connecting multiple gates.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. As semiconductor integrated circuits (ICs) and/or chips become smaller, the implementation of stacked nanosheets in semiconductor devices has increased.

### SUMMARY

Embodiments of the present disclosure relate to a semiconductor device. The semiconductor device includes a substrate, a shallow trench isolation (STI) layer formed on the substrate. The semiconductor device also includes a first gate, a second gate, and a gate strap connecting the first gate to the second gate. The gate strap is formed in the STI layer.

Embodiments of the present disclosure relate to an electronic device including a semiconductor device. The semiconductor device includes a substrate, a shallow trench isolation (STI) layer formed on the substrate. The semiconductor device also includes a first gate, a second gate, and a gate strap connecting the first gate to the second gate. The gate strap is formed in the STI layer.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a partial cross-sectional view of a semiconductor device at an intermediate stage of the fabrication process and taken along the X1-A to X1-B line of FIG. 1B, according to embodiments.

FIG. 1B is a simplified top view of the semiconductor device shown in FIGS. 1A, 1C, and 1D, according to embodiments.

FIG. 1C is a partial cross-sectional view of the semiconductor device at an intermediate stage of the fabrication process and taken along the X2-A to X2-B line of FIG. 1B, according to embodiments.

FIG. 1D is a partial cross-sectional view of the semiconductor device at an intermediate stage of the fabrication process and taken along the Y1-A to Y1-B line of FIG. 1D, according to embodiments.

FIG. 2A is a partial cross-sectional view of the semiconductor device of FIG. 1A at a subsequent stage of the fabrication process and taken along the X1-A to X1-B line of FIG. 1B, according to embodiments.

FIG. 2B is a partial cross-sectional view of the semiconductor device of FIG. 1C at a subsequent stage of the fabrication process and taken along the X2-A to X2-B line of FIG. 1B, according to embodiments.

FIG. 2C is a partial cross-sectional view of the semiconductor device of FIG. 1D at a subsequent stage of the fabrication process and taken along the Y1-A to Y1-B line of FIG. 1B, according to embodiments.

FIG. 3A is a partial cross-sectional view of the semiconductor device of FIG. 2A at a subsequent stage of the fabrication process and taken along the X1-A to X1-B line of FIG. 1B, according to embodiments.

FIG. 3B is a partial cross-sectional view of the semiconductor device of FIG. 2B at a subsequent stage of the fabrication process and taken along the X2-A to X2-B line of FIG. 1B, according to embodiments.

FIG. 3C is a partial cross-sectional view of the semiconductor device of FIG. 2C at a subsequent stage of the fabrication process and taken along the Y1-A to Y1-B line of FIG. 1B, according to embodiments.

FIG. 4A is a partial cross-sectional view of the semiconductor device of FIG. 3A at a subsequent stage of the fabrication process and taken along the X1-A to X1-B line of FIG. 1B, according to embodiments.

FIG. 4B is a partial cross-sectional view of the semiconductor device of FIG. 3B at a subsequent stage of the fabrication process and taken along the X2-A to X2-B line of FIG. 1B, according to embodiments.

FIG. 4C is a partial cross-sectional view of the semiconductor device of FIG. 3C at a subsequent stage of the fabrication process and taken along the Y1-A to Y1-B line of FIG. 1B, according to embodiments.

FIG. 5A is a partial cross-sectional view of the semiconductor device of FIG. 4A at a subsequent stage of the fabrication process and taken along the X1-A to X1-B line of FIG. 1B, according to embodiments.

FIG. 5B is a partial cross-sectional view of the semiconductor device of FIG. 4B at a subsequent stage of the fabrication process and taken along the X2-A to X2-B line of FIG. 1B, according to embodiments.

FIG. 5C is a partial cross-sectional view of the semiconductor device of FIG. 4C at a subsequent stage of the fabrication process and taken along the Y1-A to Y1-B line of FIG. 1B, according to embodiments.

FIG. 6A is a partial cross-sectional view of the semiconductor device of FIG. 5A at a subsequent stage of the fabrication process and taken along the X1-A to X1-B line of FIG. 1B, according to embodiments.

FIG. 6B is a partial cross-sectional view of the semiconductor device of FIG. 5B at a subsequent stage of the fabrication process and taken along the X2-A to X2-B line of FIG. 1B, according to embodiments.

FIG. 6C is a partial cross-sectional view of the semiconductor device of FIG. 2C at a subsequent stage of the fabrication process and taken along the Y1-A to Y1-B line of FIG. 1B, according to embodiments.

FIG. 7A is a partial cross-sectional view of the semiconductor device of FIG. 6A at a subsequent stage of the fabrication process and taken along the X1-A to X1-B line of FIG. 1B, according to embodiments.

FIG. 7B is a partial cross-sectional view of the semiconductor device of FIG. 6B at a subsequent stage of the fabrication process and taken along the X2-A to X2-B line of FIG. 1B, according to embodiments.

FIG. 7C is a partial cross-sectional view of the semiconductor device of FIG. 6C at a subsequent stage of the fabrication process and taken along the Y1-A to Y1-B line of FIG. 1B, according to embodiments.

FIG. 8A is a partial cross-sectional view of the semiconductor device of FIG. 7A at a subsequent stage of the fabrication process and taken along the X1-A to X1-B line of FIG. 1B, according to embodiments.

FIG. 8B is a partial cross-sectional view of the semiconductor device of FIG. 7B at a subsequent stage of the fabrication process and taken along the X2-A to X2-B line of FIG. 1B, according to embodiments.

FIG. 8C is a partial cross-sectional view of the semiconductor device of FIG. 7C at a subsequent stage of the fabrication process and taken along the Y1-A to Y1-B line of FIG. 1B, according to embodiments.

FIG. 9A is a partial cross-sectional view of the semiconductor device of FIG. 8A at a subsequent stage of the fabrication process and taken along the X1-A to X1-B line of FIG. 1B, according to embodiments.

FIG. 9B is a partial cross-sectional view of the semiconductor device of FIG. 8B at a subsequent stage of the fabrication process and taken along the X2-A to X2-B line of FIG. 1B, according to embodiments.

FIG. 9C is a partial cross-sectional view of the semiconductor device of FIG. 8C at a subsequent stage of the fabrication process and taken along the Y1-A to Y1-B line of FIG. 1B, according to embodiments.

FIG. 10A is a partial cross-sectional view of the semiconductor device of FIG. 9A at a subsequent stage of the fabrication process and taken along the X1-A to X1-B line of FIG. 1B, according to embodiments.

FIG. 10B is a partial cross-sectional view of the semiconductor device of FIG. 9B at a subsequent stage of the fabrication process and taken along the X2-A to X2-B line of FIG. 1B, according to embodiments.

FIG. 10C is a partial cross-sectional view of the semiconductor device of FIG. 9C at a subsequent stage of the fabrication process and taken along the Y1-A to Y1-B line of FIG. 1B, according to embodiments.

FIG. 11A is a partial cross-sectional view of the semiconductor device of FIG. 10A at a subsequent stage of the fabrication process and taken along the X1-A to X1-B line of FIG. 1B, according to embodiments.

FIG. 11B is a partial cross-sectional view of the semiconductor device of FIG. 10B at a subsequent stage of the fabrication process and taken along the X2-A to X2-B line of FIG. 1B, according to embodiments.

FIG. 11C is a partial cross-sectional view of the semiconductor device of FIG. 10C at a subsequent stage of the fabrication process and taken along the Y1-A to Y1-B line of FIG. 1B, according to embodiments.

### DETAILED DESCRIPTION

The present disclosure describes semiconductor devices including a gate strap structure that electrically connects more than one gate together, and the gate strap structure is formed under the gates in a shallow trench isolation region of the semiconductor device.

Having a gate contact (also referred to herein as a VB contact) that electrically connects to multiple gates may be beneficial for the middle of line (MOL) to enable different device performance characteristics. As used herein, the term “gate strap” or “gate strap structure” refers to a gate contact structure that spans the width of at least two gates and is electrically connected to each of these multiple gates. In certain semiconductor structures, when a gate contact connects to more than one gate, this gate contact may have to be formed to a greater width (e.g., to roughly the distance of a pitch between the two gates) in order to ensure these electrical connections. However, when the gate contact is formed to this greater width, one or more edges of the gate contact might be very close to one or more adjacent metal contacts in or near the middle of line (MOL) region. The proximity between the gate contact and the adjacent metal contacts may increase the potential to cause undesirable electrical shorting between the gate contact and these other metal contacts.

However, in the present embodiments, by forming the gate strap under the gates (i.e., rather than on top of the gates) in, for example, a shallow trench isolation (STI) region, this wider portion of the gate strap is formed lower in the vertical profile of the semiconductor device and further away from the MOL region. Consequently, only a single gate contact needs to be formed on the top of the gates to connect to the MOL. This single gate contact on top of the gates may then be formed to a smaller width because it does not need to bridge the entire distance between adjacent gates (i.e., because the gate strap on the bottom already accomplishes this connection). This may reduce any congestion in the upper layers and therefore reduce the likelihood of electrical shorting between the single gate contact and any adjacent metal contacts in the higher layers of the semiconductor device near the MOL region. Because of the continuing trend toward reducing dimensions of the various individual structures in such semiconductor devices, it may be desirable to increase the flexibility with regard to where this gate strap is formed to reduce the potential for electrical shorting.

The flowcharts and cross-sectional diagrams in the Figures illustrate methods of manufacturing semiconductor devices according to various embodiments. In some alternative implementations, the manufacturing steps may occur in a different order than that is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the particular drawing figures. Several of the figures show different orientation such as the top view, and different cross-sectional views. It should be noted that right and left, or top and bottom, etc. relate to (or depend on) the particular view of each figure. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions.

The wafer footprint of a FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

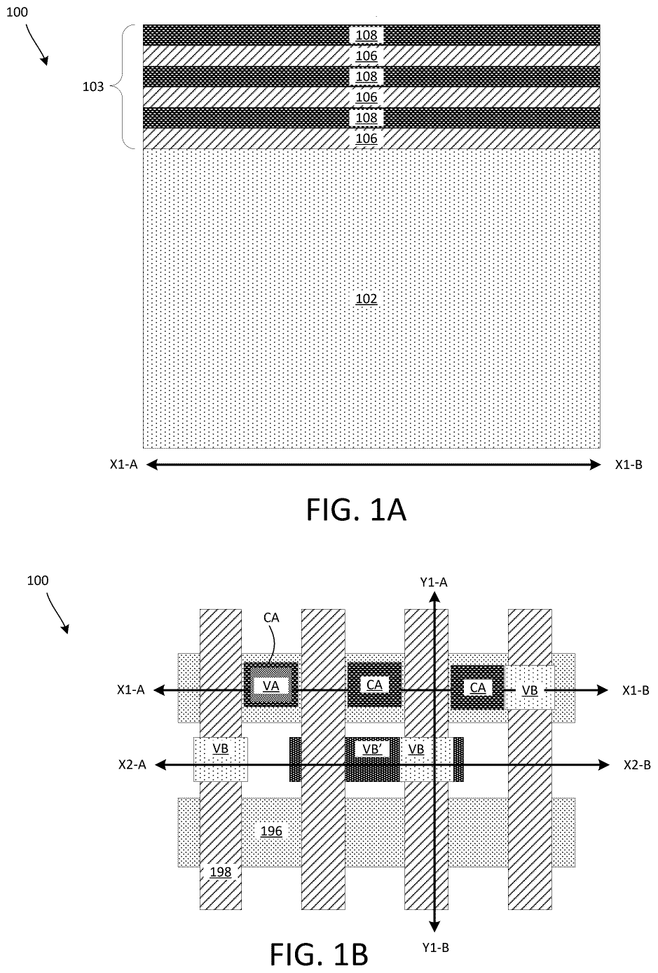

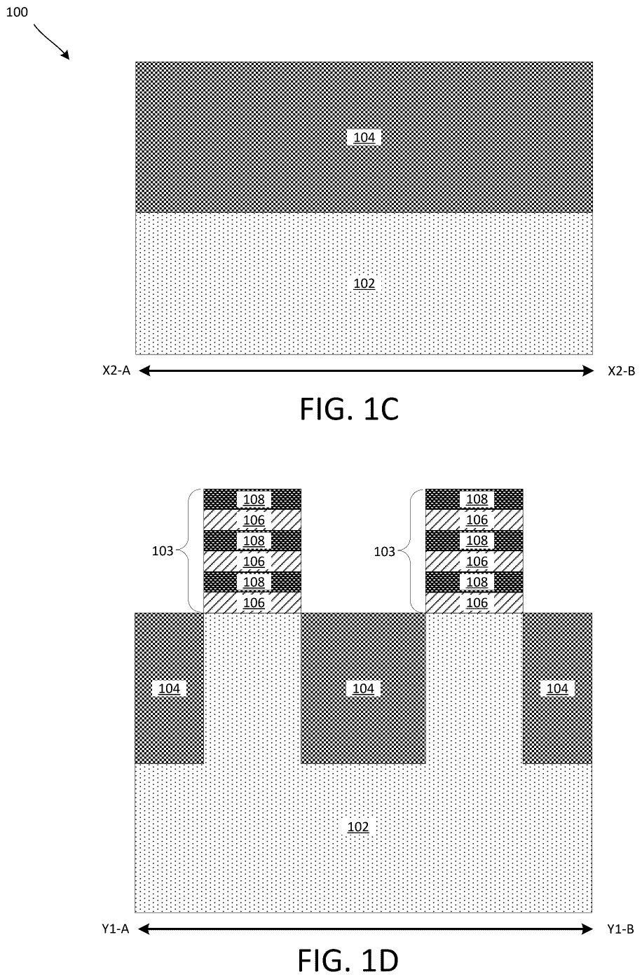

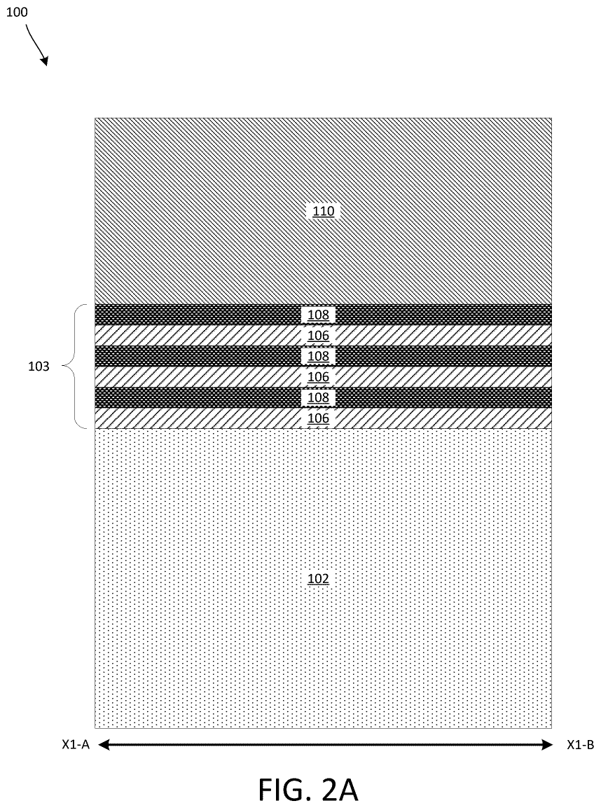

Referring now to the drawings in which like numerals represent the same or similar elements and initially to FIG. 1B, this figure is a simplified top-down (or plan) view of the semiconductor device 100 and shows the general locations of the active regions 196 (sometimes abbreviated as RX) and gate regions 198 (sometimes abbreviated as PC) of the semiconductor device 100. FIG. 1B also shows the general regions where gate contacts VB, a source/drain metal layer CA, source/drain contacts VA, and gate straps VB′ are formed in plan view. It should be appreciated that the scale and locations of these various regions are approximations and are merely intended to show where certain components and regions are relative to others from a top-down perspective.

Referring now to FIG. 1A, this figure is a partial cross-sectional view of a semiconductor device 100 at an intermediate stage of the fabrication process and taken along the X1-A to X1-B line of FIG. 1B, according to embodiments. As shown in FIG. 1A, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 102 is entirely composed of at least one semiconductor material. It should be appreciated that the substrate 102 may be comprised of any other suitable material(s) than those listed above.

Referring again to FIG. 1A, the semiconductor device 100 includes a nanosheet stack 103 formed on the substrate 102. The nanosheet stack 103 initially includes a first sacrificial layer 106 formed on the substrate 102, followed by the formation of a semiconductor layer 108. In an example, the sacrificial layer 106 is composed of silicon-germanium (e.g., Si—Ge, or more generally, where the Ge ranges from about 15-35%). Next, the first (or bottommost) semiconductor layer 108 is formed on an upper surface of the bottommost sacrificial layer 106. In an example, the semiconductor layer 108 is composed of silicon. Several additional layers of the sacrificial layer 106 and the semiconductor layer 108 are alternately formed. It should be appreciated that any suitable number of alternating layers of sacrificial layers 106 and semiconductor layers 108 may be formed.

In certain embodiments, the sacrificial layers 106 have a vertical thickness ranging, for example, from approximately 3 nm to approximately 20 nm. In certain embodiments, the semiconductor layers 108 have a vertical thickness ranging, for example, from approximately 3 nanometers (nm) to approximately 10 nm. Although the range of 3-20 nm is cited as an example range of thickness, other thicknesses of these layers may be used. In certain embodiments, certain of the sacrificial layers 106 and/or the semiconductor layers 108 may have different thicknesses relative to one another. Therefore, multiple epitaxial growth processes can be performed to form the sacrificial layers 106 and the semiconductor layers 108.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers 106.

Referring now to FIGS. 1C and 1D, the nanosheet stacks 103 are at stage of the manufacturing process where they have already been patterned using one or more suitable lithography and material removal steps. As shown in FIGS. 1C and 1D, the patterning is performed on the nanosheet stacks 103, and the shallow trench isolation regions 104 are formed into the substrate 102. As shown in detail in FIG. 1D, the shallow trench isolation (STI) regions 104 are formed in the substrate 102 between adjacent nanosheet stacks 103. In general, shallow trench isolation is an integrated circuit feature which prevents electric current leakage between adjacent semiconductor device components. STI is generally used on CMOS process technology nodes of 250 nanometers and smaller. STI regions 104 are created early during the semiconductor device 100 fabrication process before transistors are formed. The key steps of the STI process involve etching a pattern of trenches in the silicon, depositing one or more dielectric materials (such as silicon dioxide) to fill the trenches, and removing the excess dielectric using a technique such as chemical-mechanical planarization.

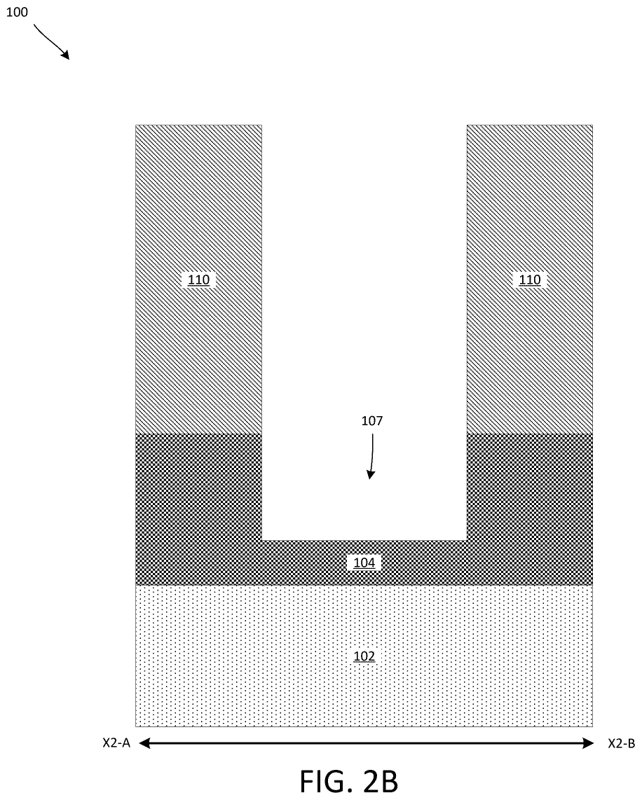

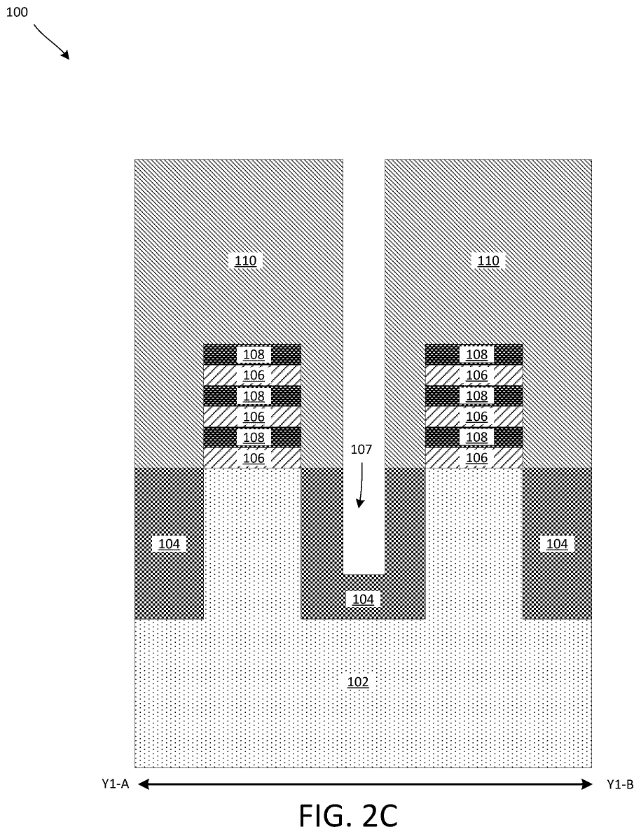

Referring now to FIG. 2A, this figure is a partial cross-sectional view of the semiconductor device 100 of FIG. 1A at a subsequent stage of the fabrication process and taken along the X1-A to X1-B line of FIG. 1B, according to embodiments. Similarly, FIG. 2B is a partial cross-sectional view of the semiconductor device 100 of FIG. 1C at a subsequent stage of the fabrication process and taken along the X2-A to X2-B line of FIG. 1B, and FIG. 2C is a partial cross-sectional view of the semiconductor device 100 of FIG. 1D at a subsequent stage of the fabrication process and taken along the Y1-A to Y1-B line of FIG. 1B, according to embodiments. As shown in FIGS. 2A-2C, a first organic planarization (OPL) layer 110 is formed over the STI regions 104 and over the nanosheet stacks 103. The first OPL layer 110 is then patterned to allow for the subsequent removal of portions of the STI regions 104. In particular, as shown in FIG. 2B, an STI opening 107 (this may also be referred to as a trench or a recess) is formed in the middle region of the first OPL layer 110. Also, as shown in FIG. 2C, an opening is also formed in the middle region of the first OPL layer 110 between two of the adjacent nanosheet stacks 103. Then, a suitable material removal process is used to remove some of the STI regions 104. However, it should be appreciated that in certain embodiments, as shown in FIGS. 2B and 2C, some thickness of the material of the STI region 104 remains on the substrate 102 to allow for an insulative barrier between the substrate 102 and subsequent layers that are formed on the STI regions 104.

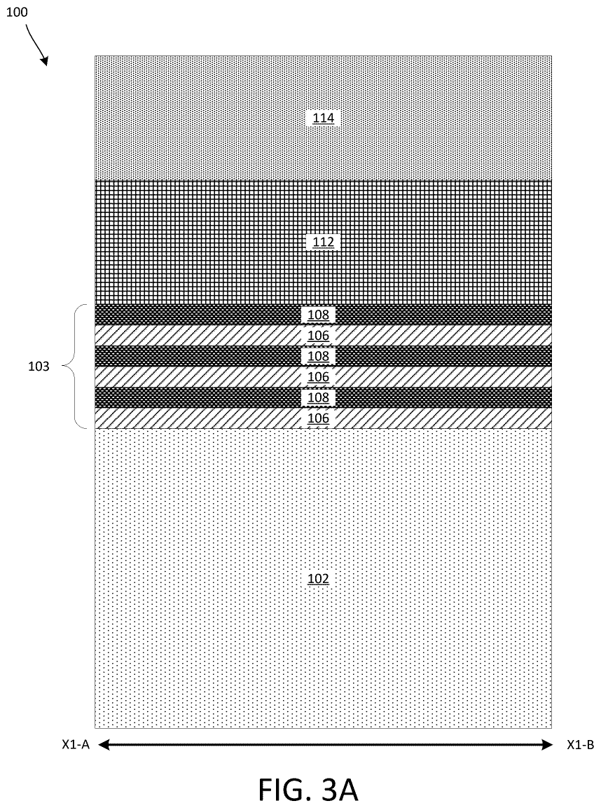

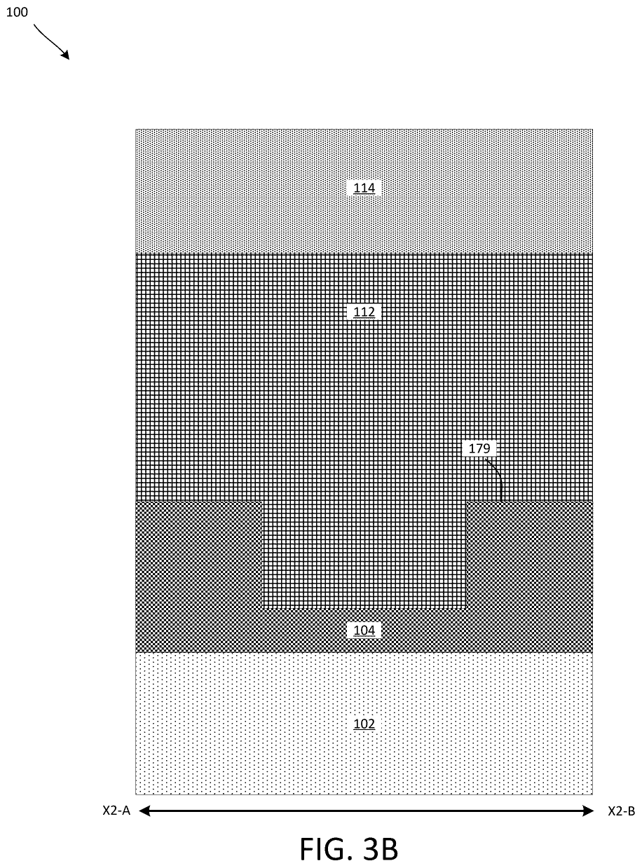

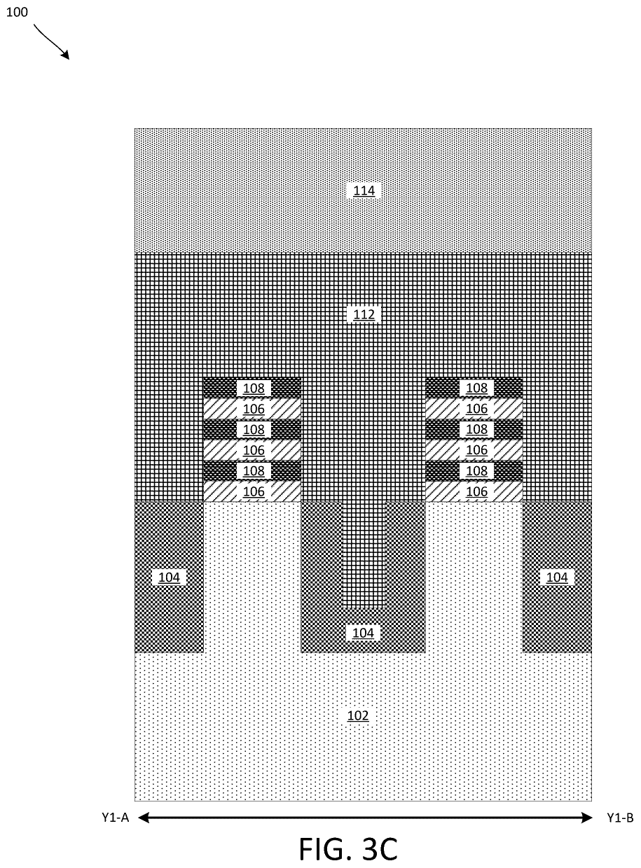

Referring now to FIG. 3A, this figure is a partial cross-sectional view of the semiconductor device 100 of FIG. 2A at a subsequent stage of the fabrication process and taken along the X1-A to X1-B line of FIG. 1B, according to embodiments. Similarly, FIG. 3B is a partial cross-sectional view of the semiconductor device 100 of FIG. 2B at a subsequent stage of the fabrication process and taken along the X2-A to X2-B line of FIG. 1B, and FIG. 3C is a partial cross-sectional view of the semiconductor device 100 of FIG. 2C at a subsequent stage of the fabrication process and taken along the Y1-A to Y1-B line of FIG. 1B. As shown in each of FIGS. 3A to 3C, after the formation of the STI openings 107 in the STI region 104, a suitable material removal process is used to remove the first OPL layer 110. Then, a dummy gate 112 (or dummy polycrystalline (PC) layer) is formed on the nanosheet stacks 103, on the STI regions 104, and in the STI openings 107 that were previously formed in the STI regions 104. The dummy gate 112 may be formed by any suitable deposition technique known to one of skill in the art. In one example, the dummy gate 112 is formed by depositing a thin SiO₂ dummy gate oxide layer (not shown), followed by depositing a layer of amorphous silicon (a-Si) as the dummy gate 112. In certain examples, the dummy gate 112 may be composed of polycrystalline silicon (poly silicon), amorphous silicon, and/or an oxide, such as, SiO₂. Thus, as shown in FIGS. 3B and 3C, the dummy gate 112 is formed in the STI region 104 trenches below an upper surface 179 of the STI regions 104. Also, as shown in FIGS. 3A-3C, a gate hardmask 114 is formed on the dummy gate 112.

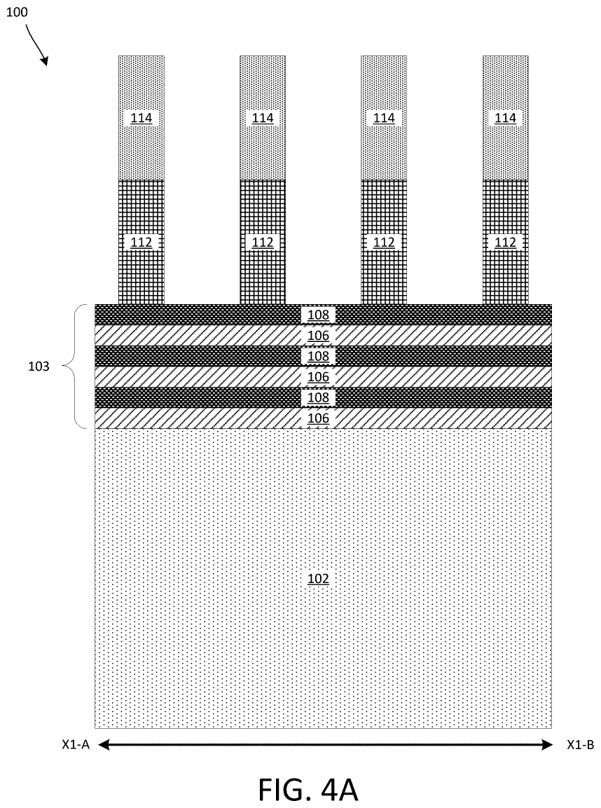

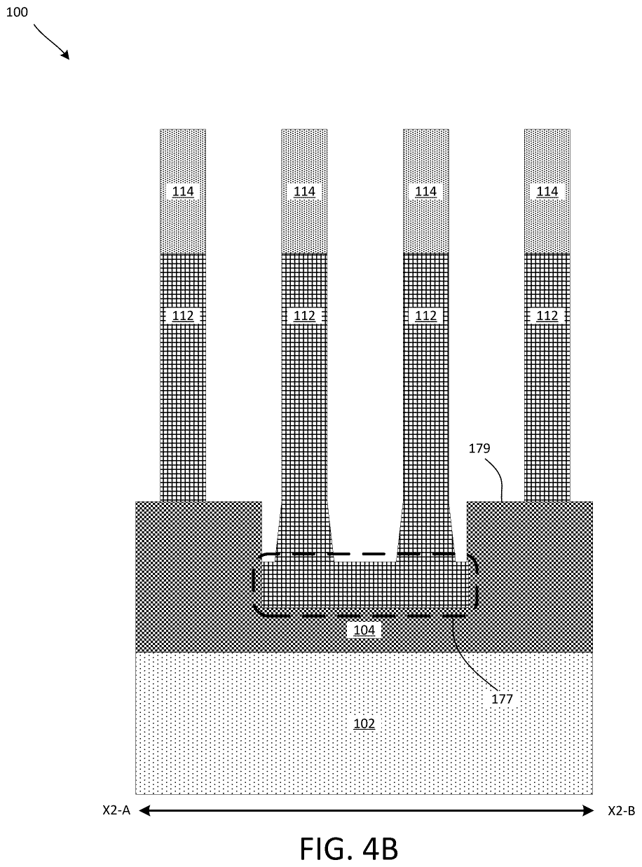

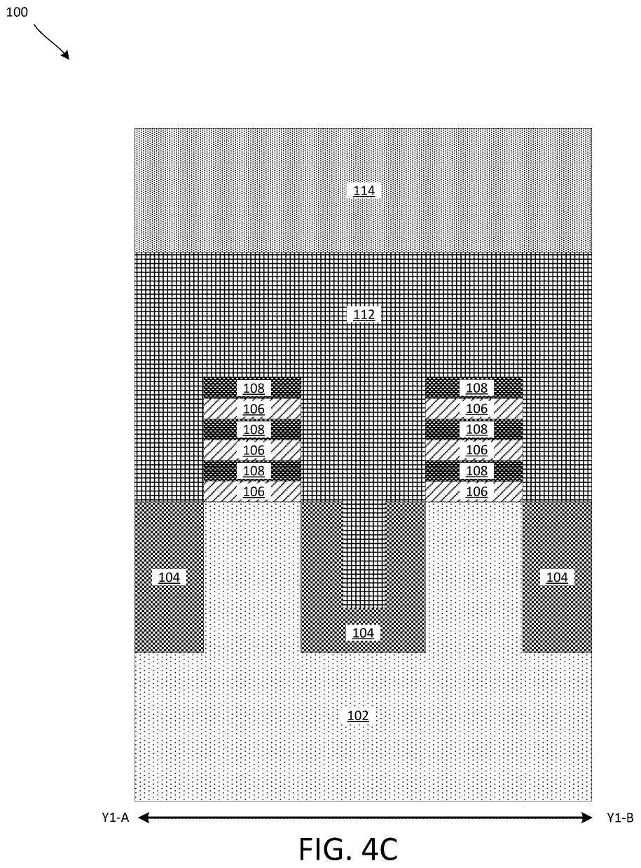

Referring now to FIG. 4A, this figure is a partial cross-sectional view of the semiconductor device 100 of FIG. 3A at a subsequent stage of the fabrication process and taken along the X1-A to X1-B line of FIG. 1B, according to embodiments. Similarly, FIG. 4B is a partial cross-sectional view of the semiconductor device 100 of FIG. 3B at a subsequent stage of the fabrication process and taken along the X2-A to X2-B line of FIG. 1B, and FIG. 4C is a partial cross-sectional view of the semiconductor device 100 of FIG. 3C at a subsequent stage of the fabrication process and taken along the Y1-A to Y1-B line of FIG. 1B. As shown in FIGS. 4A and 4B, the dummy gate 112 is patterned using the gate hardmask 114 as a mask to perform the patterning. The gate patterning may be performed by first patterning the gate hardmask 114 and then using the patterned gate hardmask to etch the dummy gates 112.

In FIG. 4A, portions of the dummy gate 112 that are not underneath the gate hardmask 114 are removed all the way down to the top of the nanosheet stack 103. In FIG. 4B, portions of the dummy gate 112 in areas that are not underneath the gate hardmask 114 are removed down to a level that is below a top surface 179 of the STI regions 104. However, as shown in FIG. 4B, a certain amount of the dummy gate 112 is not removed in a gate strap area 177 so that the remaining portion of the dummy gate 112 in this gate strap area 117 extends all the way across the trench that was previously formed in the STI regions 104. As described in further detail below, this remaining portion of the dummy gate 112 bridges the span between the middle two dummy gates 112, and this will allow for the subsequent formation of the gate strap in this area. There are no changes between FIG. 4C and FIG. 3C.

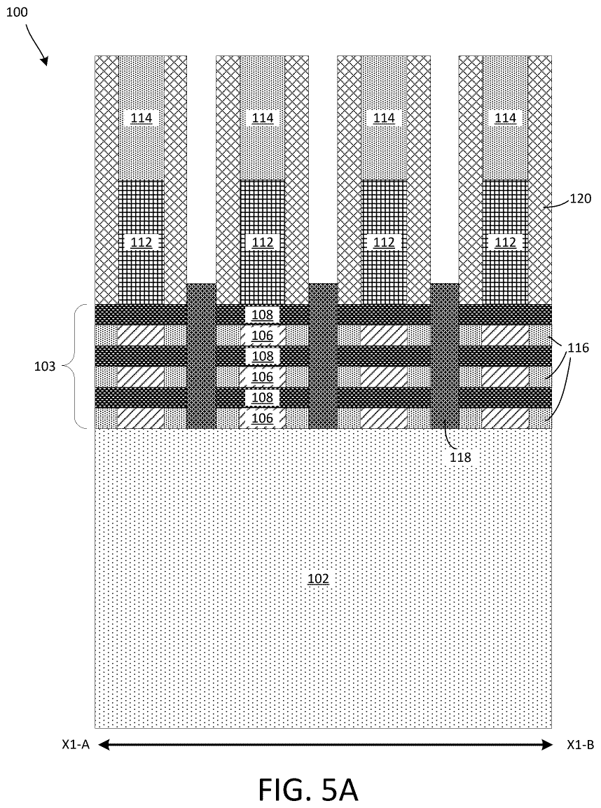

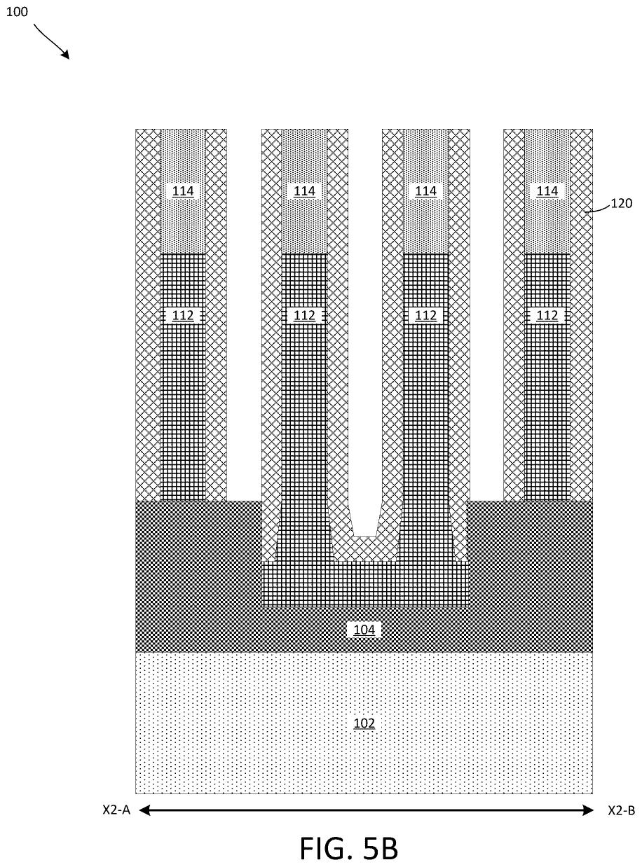

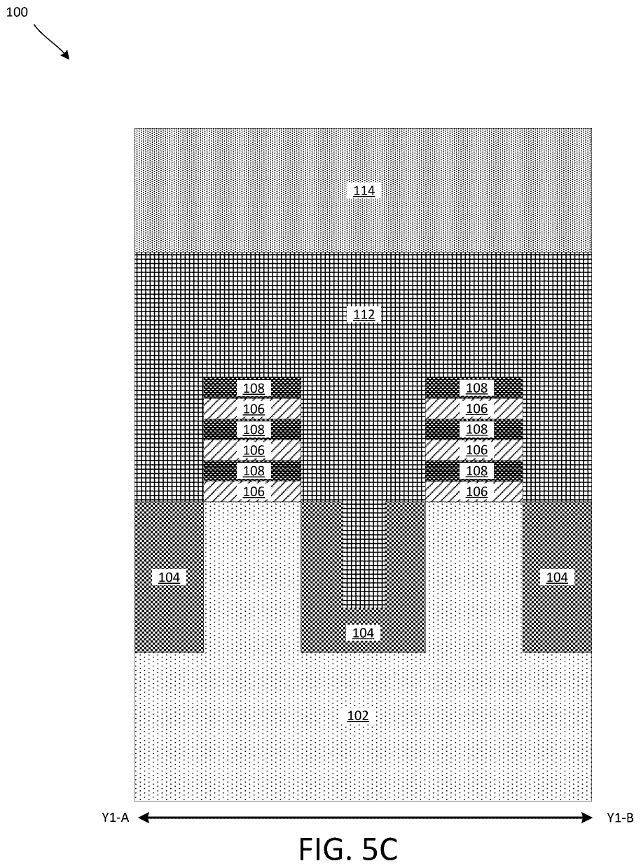

Referring now to FIG. 5A, this figure is a partial cross-sectional view of the semiconductor device 100 of FIG. 4A at a subsequent stage of the fabrication process and taken along the X1-A to X1-B line of FIG. 1B, according to embodiments. Similarly, FIG. 5B is a partial cross-sectional view of the semiconductor device 100 of FIG. 4B at a subsequent stage of the fabrication process and taken along the X2-A to X2-B line of FIG. 1B, and FIG. 5C is a partial cross-sectional view of the semiconductor device 100 of FIG. 4C at a subsequent stage of the fabrication process and taken along the Y1-A to Y1-B line of FIG. 1B.

As shown in FIGS. 5A and 5B, after the dummy gate 112 is formed, a spacer material is conformally deposited, forming the gate electrode spacer layers 120. Then, a suitable material removal process (e.g., reactive ion etching) is used to recess the nanosheet stacks 103 in areas not covered by the gate hardmask 114 and the gate electrode spacers layer 120 down to a level of the substrate 102. After that, the nanosheet stacks 103 at the source/drain regions which are not protected by gate hardmask 114 and gate electrode spacer layers 120 are recessed in a horizontal direction, followed by inner spacer 116 formation. A selective etching process using, for example, a boron-based chemistry or a chlorine-based chemistry may be used, which selectively recesses the exposed portions of the sacrificial layers 106 without significantly attacking the surrounding materials (e.g., the semiconductor layers 108). Then, the inner spacers 116 are formed in the indents created by the removal of the portions of the sacrificial layers 106. An optional isotropic etching process may be performed to clean up the edges of the inner spacers 116. Then, as shown in FIG. 5A, source/drain epitaxial layers 118 are formed on the substrate 102 between the nanosheet stacks 103. In certain examples, the source/drain epitaxial layers 118 may be formed to a height that is at or somewhat above an upper surface of the nanosheet stacks. There are no differences between FIG. 5C and FIG. 4C.

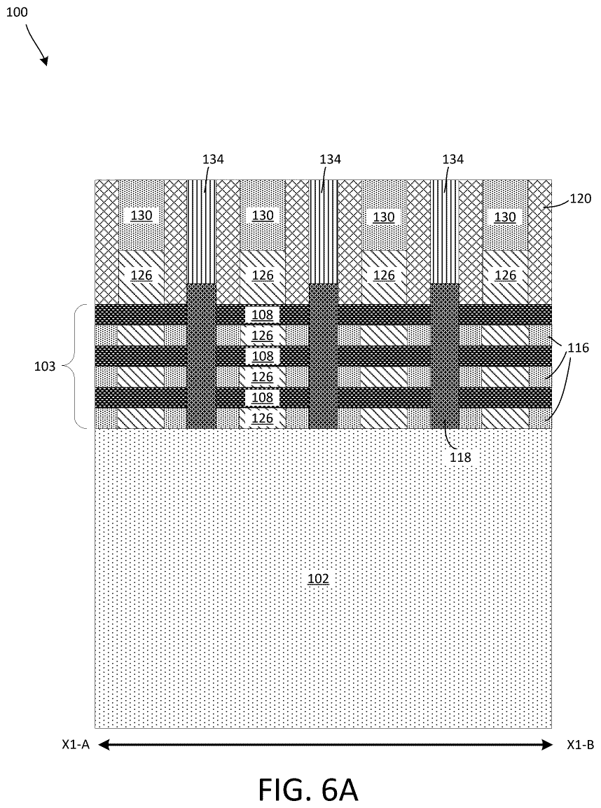

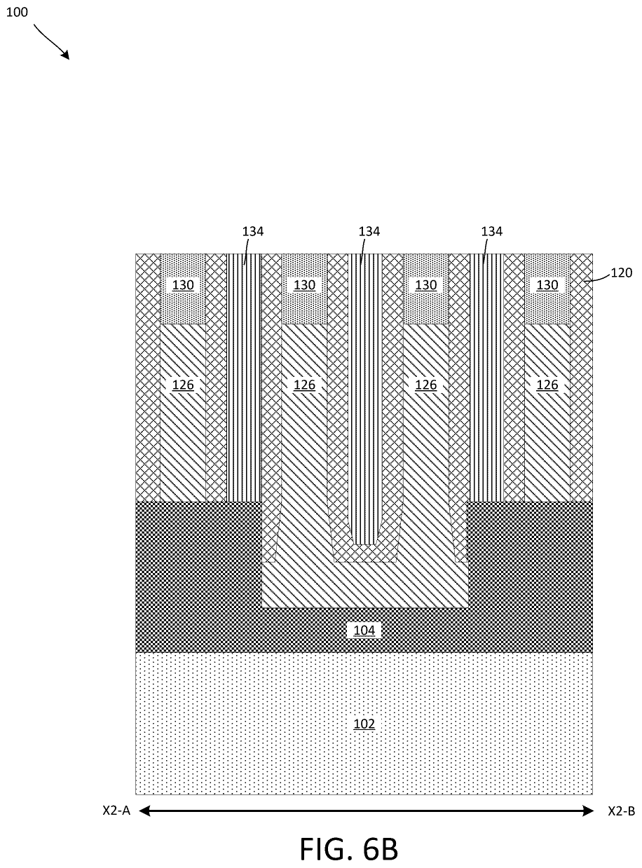

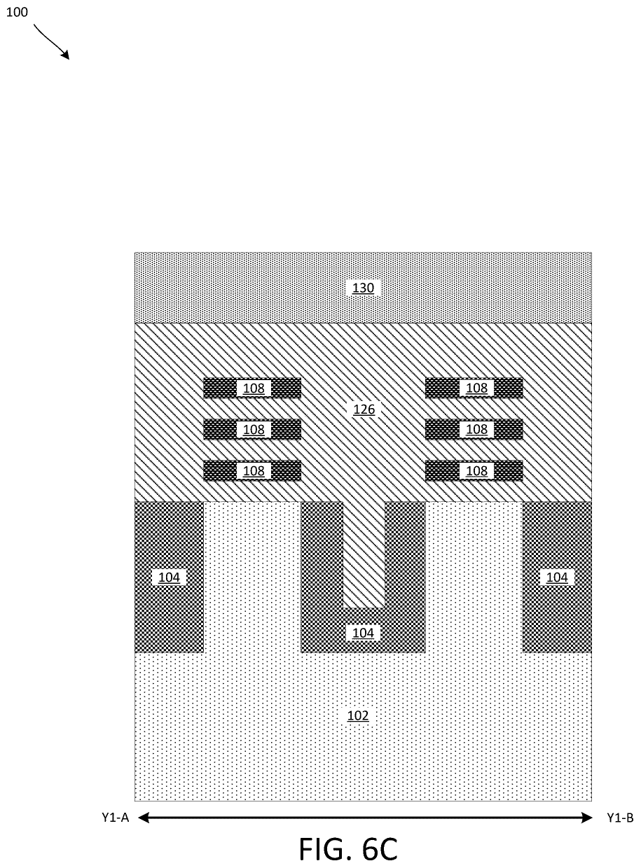

Referring now to FIG. 6A, this figure is a partial cross-sectional view of the semiconductor device 100 of FIG. 5A at a subsequent stage of the fabrication process and taken along the X1-A to X1-B line of FIG. 1B, according to embodiments. Similarly, FIG. 6B is a partial cross-sectional view of the semiconductor device 100 of FIG. 5B at a subsequent stage of the fabrication process and taken along the X2-A to X2-B line of FIG. 1B, and FIG. 6C is a partial cross-sectional view of the semiconductor device 100 of FIG. 5C at a subsequent stage of the fabrication process and taken along the Y1-A to Y1-B line of FIG. 1B. As shown in FIGS. 6A-6C, a second ILD layer 134 is formed over the source/drain epitaxial layers 118. Then, after removal of the gate hardmask 114, a gate cut patterning process is performed (not shown) to etch away the dummy gate 112 in a gate cut region, followed by filling the gate cut region with dielectric material (not shown). Then, the dummy gate 112 is selectively removed, followed by removal of (or release of) the SiGe material of the sacrificial layers 106.

After the material of the sacrificial layers 106 has been released, a high-k metal gate (HKMG) stack 126 is formed in the spaces created by the previous removal of the gate hardmask 114, the SiGe material of the sacrificial layers 106, and the dummy gate 112. In certain embodiments, the forming of the HKMG stack 126 includes first forming a continuous layer of gate dielectric material (not shown for the sake of simplicity) and then forming a gate electrode metal layer inside the gate opening. The continuous layer of gate dielectric material can include silicon oxide, or a dielectric material having a dielectric constant greater than 4.0 (such dielectric materials can be referred to as a high-K metal gate dielectric material). Illustrative examples of high-K gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The HKMG dielectric layer dielectric material can further include dopants such as lanthanum (La), aluminum (Al) and/or magnesium (Mg). The continuous layer of the high-K metal gate can be formed utilizing a deposition process such as, for example, ALD, CVD, PECVD, or PVD. It should be appreciated that a chemical mechanical planarization (CMP) process can be applied to the top surface.

Referring back to FIGS. 6A-6C, the gate electrode metal layer of the HKMG stack 126 may include an NFET work function metal (WFM) material or a PFET WFM material, which is deposited in the spaces created by the previous removal of the sacrificial layers 106 in the nanosheet stack 103. The different WFM layers form the overall HKMG stack 126 structures. The layer of WFM can be used to set a threshold voltage of the FET to a desired value. In some embodiments, the layer of WFM can be selected to effectuate an n-type threshold voltage shift. “N-type threshold voltage shift” as used herein means a shift in the effective work-function of the work-function metal-containing material towards a conduction band of silicon in a silicon-containing material. In solid-state physics, the work function is the minimum thermodynamic work (i.e., energy) needed to remove an electron from a solid to a point in the vacuum immediately outside the solid surface. Also, this energy (work function) is a measure of how firmly a particular metal holds its electrons. In general, the conduction band is the range of permissible energy values which an electron in a solid material can have that allows the electron to dissociate from a particular atom and become a free charge carrier in the material. In one embodiment, the work function of the n-type work function metal ranges from approximately 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the layer of WFM can be selected to effectuate a p-type threshold voltage shift. In one embodiment, the work function of the p-type work function metal ranges from approximately 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. In general, the valence band is the range of permissible energy values that are the highest energies an electron can have and still be associated with a particular atom of a solid material. Examples of such materials that can effectuate a p-type threshold voltage shift include, but are not limited to, titanium nitride, and tantalum carbide, hafnium carbide, and combinations thereof. The layers of WFM are conformal layers which can be formed by a conformal deposition process such as, for example, ALD, CVD or PECVD. The layer of WFM layer can have a thickness in the range of approximately 1 nm to 20 nm, although other thicknesses above or below this range may be used as desired for a particular application.

As also shown in FIG. 6A, source/drain epitaxial layers 118 are formed on the substrate 102 between the different nanosheet stacks 103 and are formed generally to the same or similar overall height as the nanosheet stack 103. Also, a second interlayer dielectric (ILD) layer 134 is formed on the source/drain epitaxial layers 118. An additional gate electrode material layer is formed on top of the topmost semiconductor layer 108 in each of the nanosheet stacks 103, and the additional gate electrode material layer may be considered to be part of the overall HKMG stack 126 structure. In certain embodiments, an optional material removal process, such as chemical mechanical planarization (CMP) may be performed to planarize the upper surface of the overall semiconductor device 100. Then, a gate recess operation is performed to recess the material of the additional gate electrode material layer of the overall HKMG stack 126 structure to a level that is below the level of an upper surface of the second ILD layer 134. Finally, a sacrificial protective cap 130 is formed upon the HKMG stack 126 structure. Again, it should be appreciated that a chemical mechanical planarization (CMP) process can be applied to the top surface of the semiconductor device 100 at this stage.

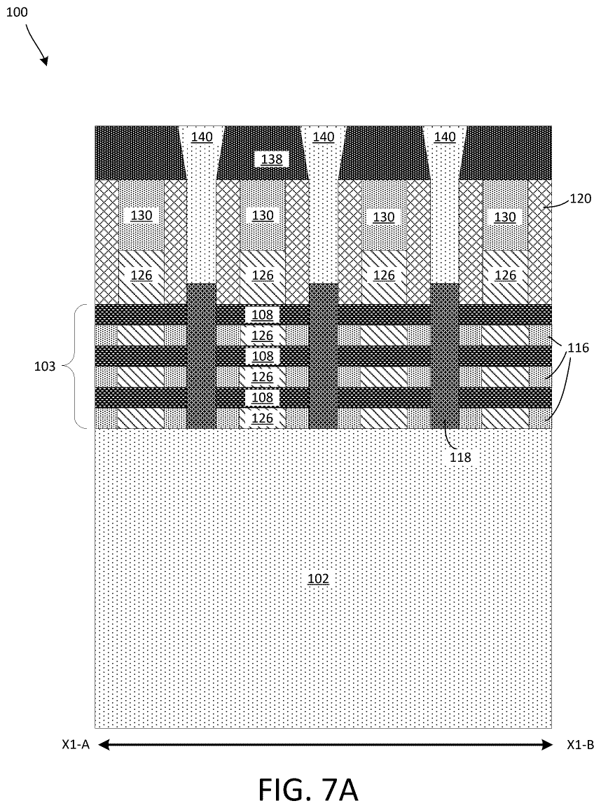

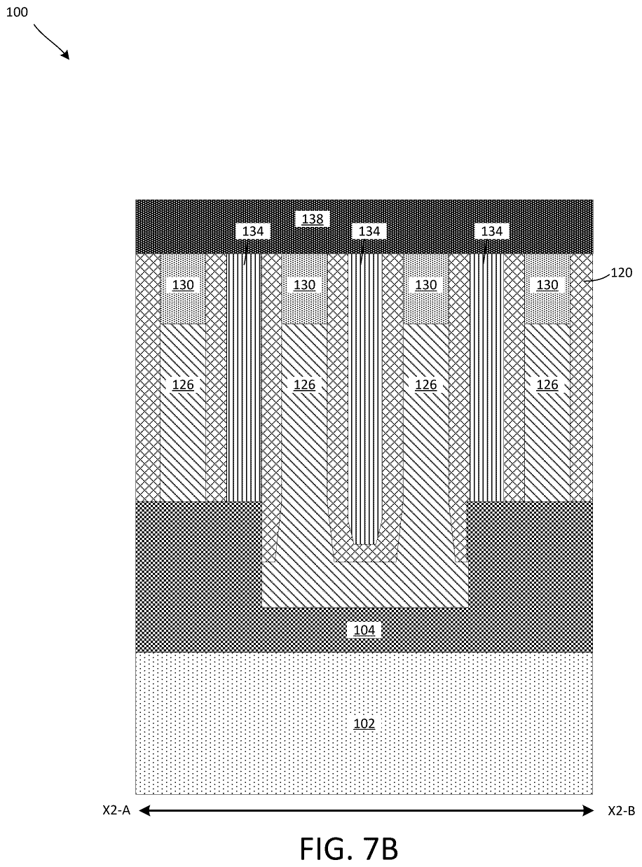

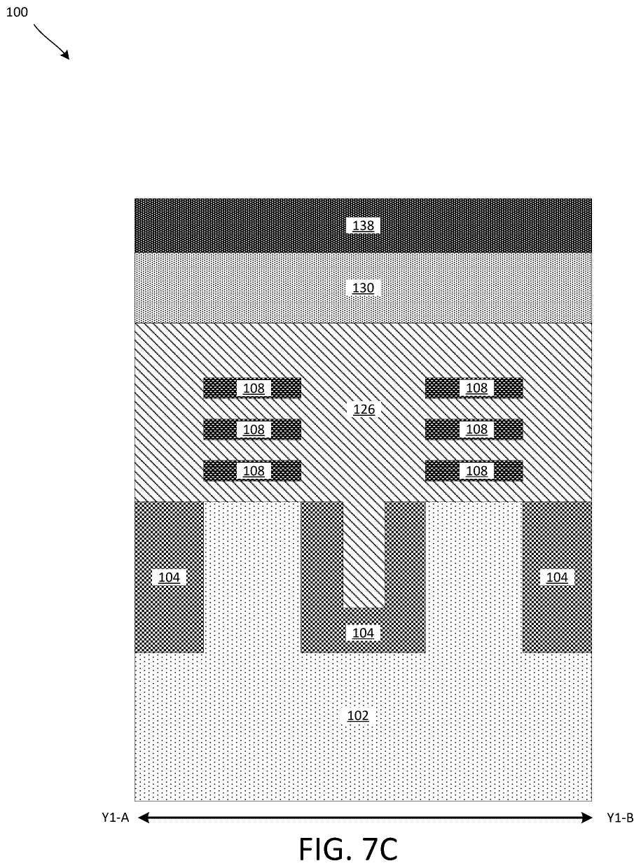

Referring now to FIG. 7A, this figure is a partial cross-sectional view of the semiconductor device 100 of FIG. 6A at a subsequent stage of the fabrication process and taken along the X1-A to X1-B line of FIG. 1B, according to embodiments. Similarly, FIG. 7B is a partial cross-sectional view of the semiconductor device 100 of FIG. 6B at a subsequent stage of the fabrication process and taken along the X2-A to X2-B line of FIG. 1B, and FIG. 7C is a partial cross-sectional view of the semiconductor device 100 of FIG. 6C at a subsequent stage of the fabrication process and taken along the Y1-A to Y1-B line of FIG. 1B. As shown in FIGS. 7A-7C, a third ILD layer 138 is formed on the top of the semiconductor device 100. Then, one or more suitable material removal processes are performed to form several contact openings (not shown) in the third ILD layer 138 and to remove the second ILD layer 134. These material removal processes temporarily expose the top surfaces of the source/drain epitaxial layers 118. Then, several source/drain metal layers 140 (also referenced as CA in FIG. 1B) are formed in the spaces created by the previous removal of the portions of the third ILD layer 138 and the second ILD layer 134.

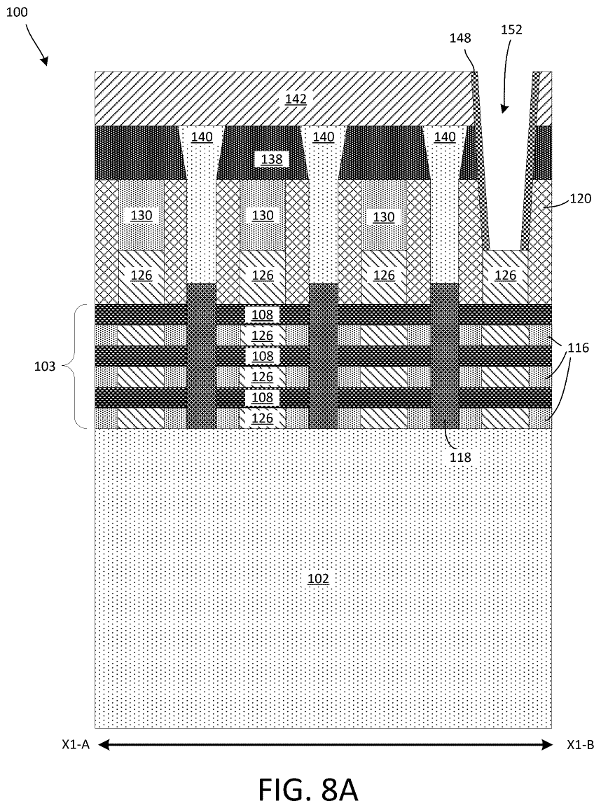

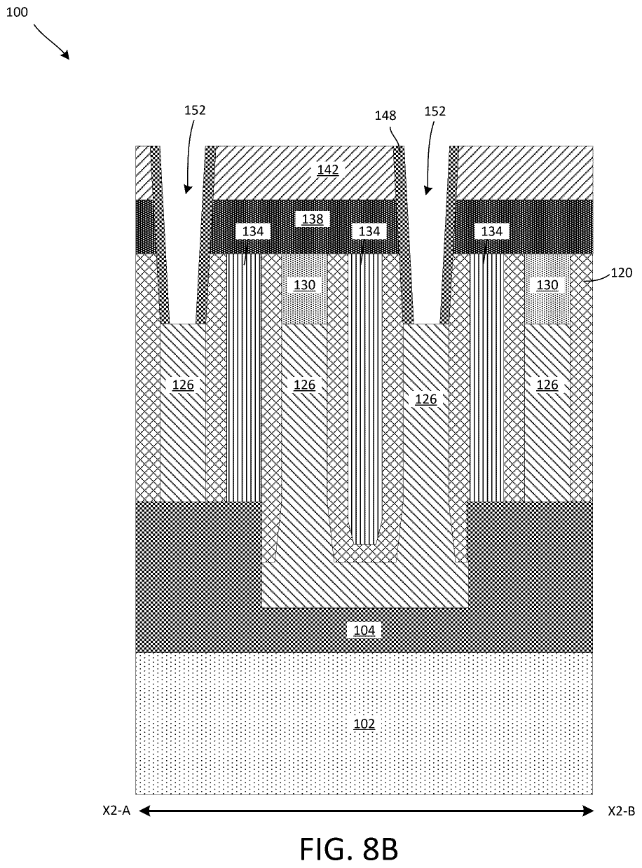

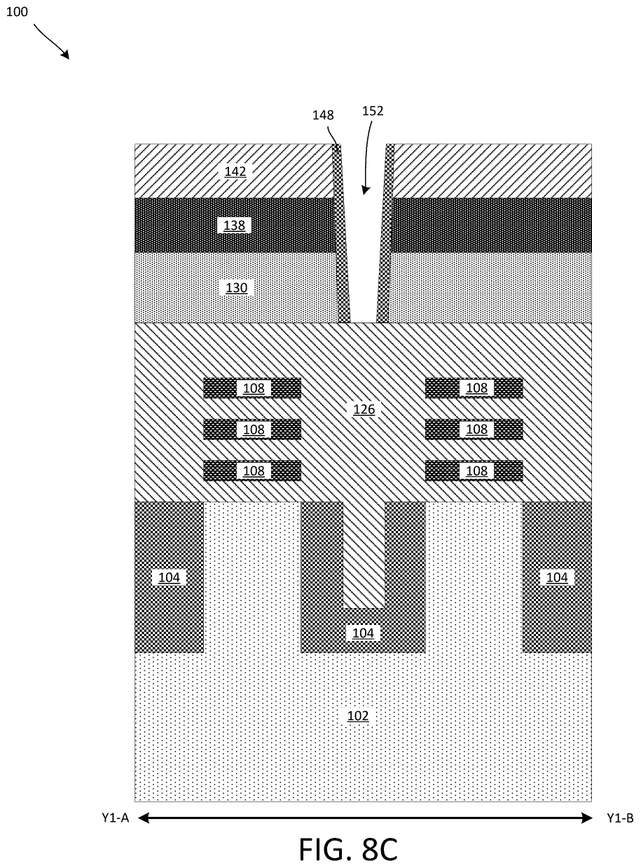

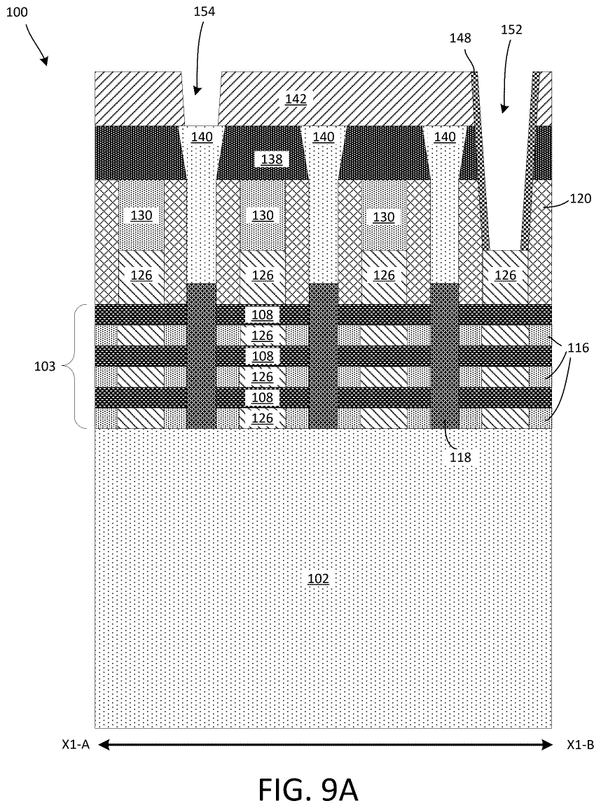

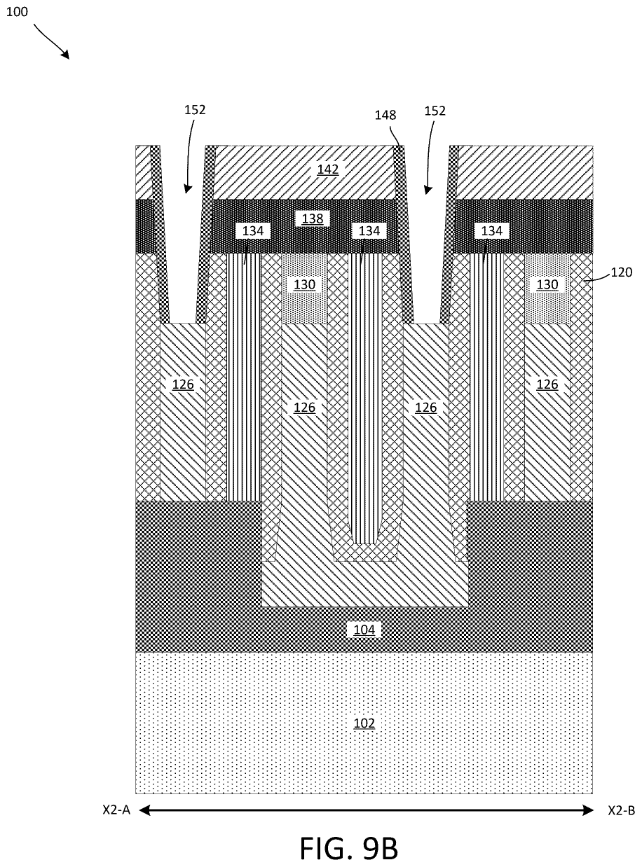

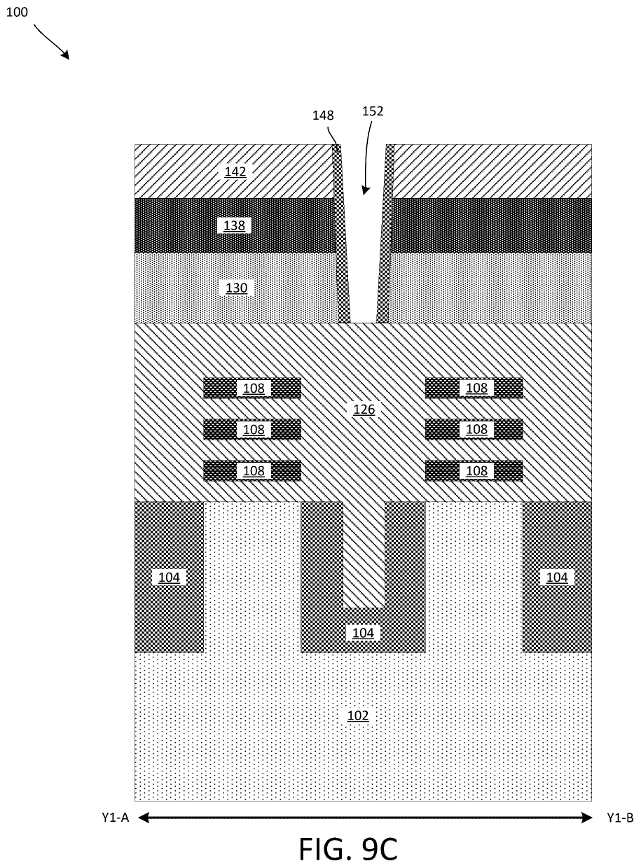

Referring now to FIG. 8A, this figure is a partial cross-sectional view of the semiconductor device 100 of FIG. 7A at a subsequent stage of the fabrication process and taken along the X1-A to X1-B line of FIG. 1B, according to embodiments. Similarly, FIG. 8B is a partial cross-sectional view of the semiconductor device 100 of FIG. 7B at a subsequent stage of the fabrication process and taken along the X2-A to X2-B line of FIG. 1B, and FIG. 8C is a partial cross-sectional view of the semiconductor device 100 of FIG. 7C at a subsequent stage of the fabrication process and taken along the Y1-A to Y1-B line of FIG. 1B. As shown in FIGS. 8A-8C, a fourth ILD layer 142 is deposited over the top of the semiconductor device 100. Then, one or more suitable material removal processes are performed to create openings 152 to allow for the formation of gate contacts (also labeled as VB in FIG. 1B). These openings 152 extend through the fourth ILD layer 142, the third ILD layer 138, and the sacrificial protective cap 130. Then, dielectric spacer layers 148 are formed on the sidewalls inside the openings 152. The dielectric spacer layers 148 may help reduce the possibility for electrical shorting between the gate contacts VB and any adjacent metal contacts (e.g., the rightmost source/drain metal layer 140 on the X1-B side of FIG. 9A). In certain embodiments, the dielectric spacer layer 148 is also in contact with the source/drain metal layer 140.

Referring now to FIG. 9A, this figure is a partial cross-sectional view of the semiconductor device 100 of FIG. 8A at a subsequent stage of the fabrication process and taken along the X1-A to X1-B line of FIG. 1B, according to embodiments. Similarly, FIG. 9B is a partial cross-sectional view of the semiconductor device 100 of FIG. 8B at a subsequent stage of the fabrication process and taken along the X2-A to X2-B line of FIG. 1B, and FIG. 9C is a partial cross-sectional view of the semiconductor device 100 of FIG. 8C at a subsequent stage of the fabrication process and taken along the Y1-A to Y1-B line of FIG. 1B. As shown in FIGS. 9A, a second opening 154 is formed in the fourth ILD layer 142 to expose the leftmost source/drain metal layer 140 (i.e., on the X1-A side). The second opening 154 will allow for the subsequent formation of another metal contact (e.g., a source/drain contact VA). There are no differences between the FIG. 9B and FIG. 8B views, or between the FIGS. 9C and 8B views.

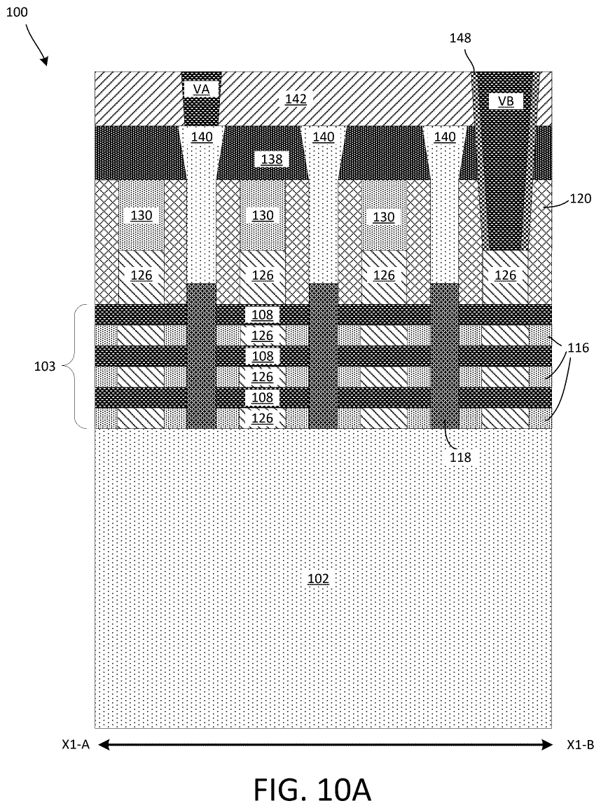

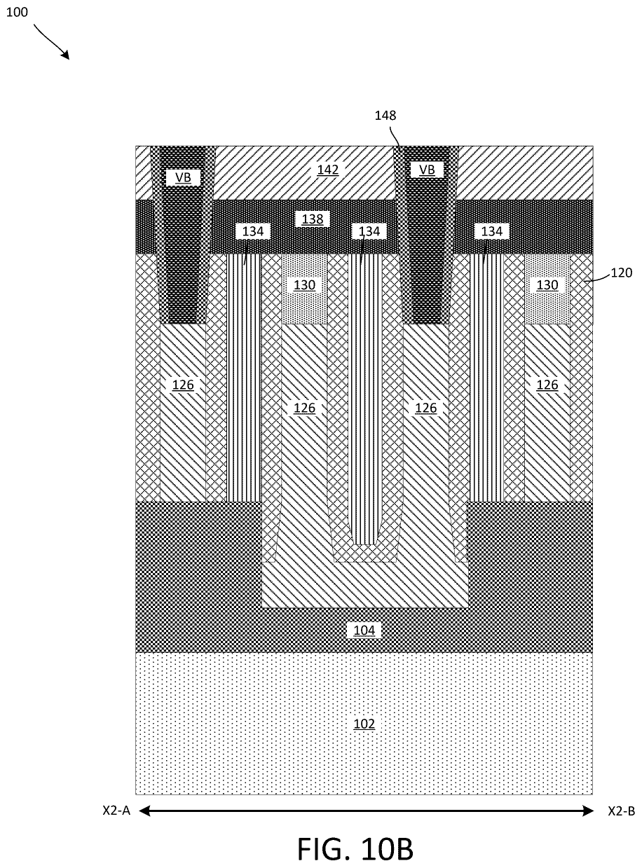

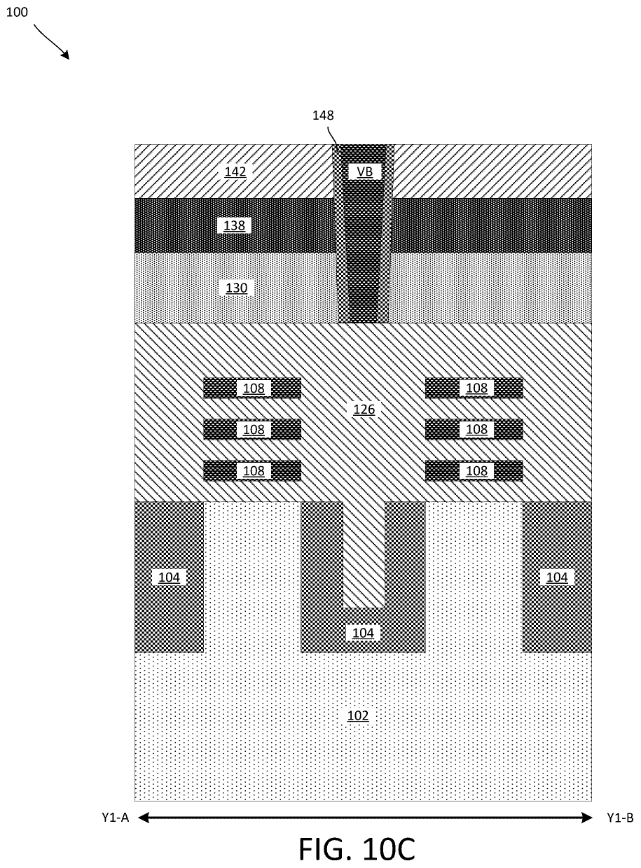

Referring now to FIG. 10A, this figure is a partial cross-sectional view of the semiconductor device 100 of FIG. 9A at a subsequent stage of the fabrication process and taken along the X1-A to X1-B line of FIG. 1B, according to embodiments. Similarly, FIG. 10B is a partial cross-sectional view of the semiconductor device 100 of FIG. 9B at a subsequent stage of the fabrication process and taken along the X2-A to X2-B line of FIG. 1B, and FIG. 10C is a partial cross-sectional view of the semiconductor device 100 of FIG. 9C at a subsequent stage of the fabrication process and taken along the Y1-A to Y1-B line of FIG. 1B. As shown in FIGS. 10A-10C, the gate contacts VB are formed in the openings 152, and the source/drain contact VA is formed in the second opening 154. The source drain contact VA and the gate contacts VB may comprise one or more suitable conductive metal materials, and these contacts may allow for further electrical connections to one or more metal line layers (e.g., an M1 layer).

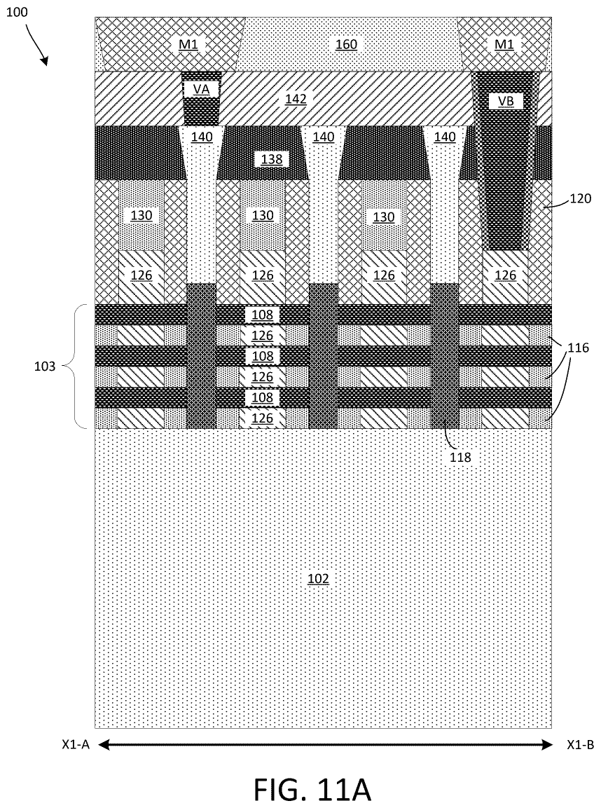

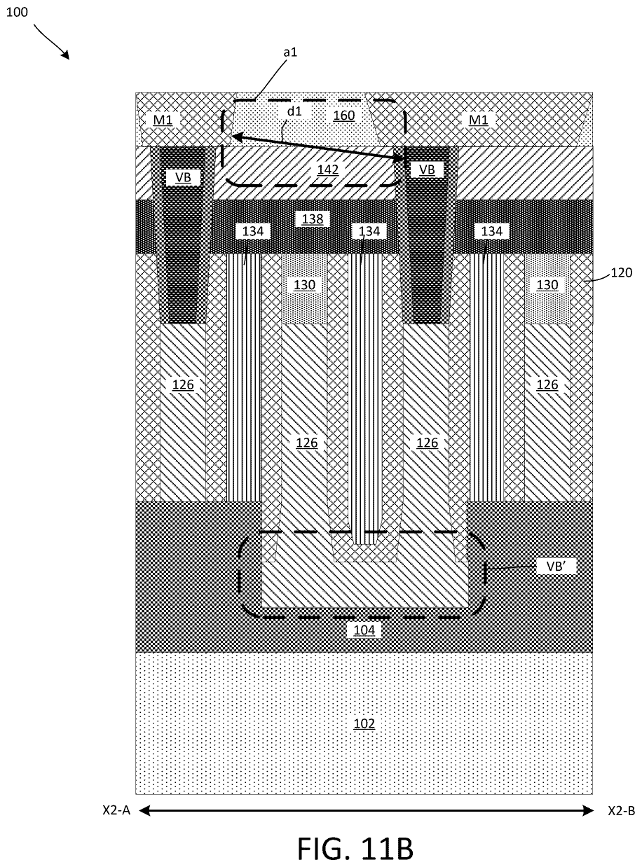

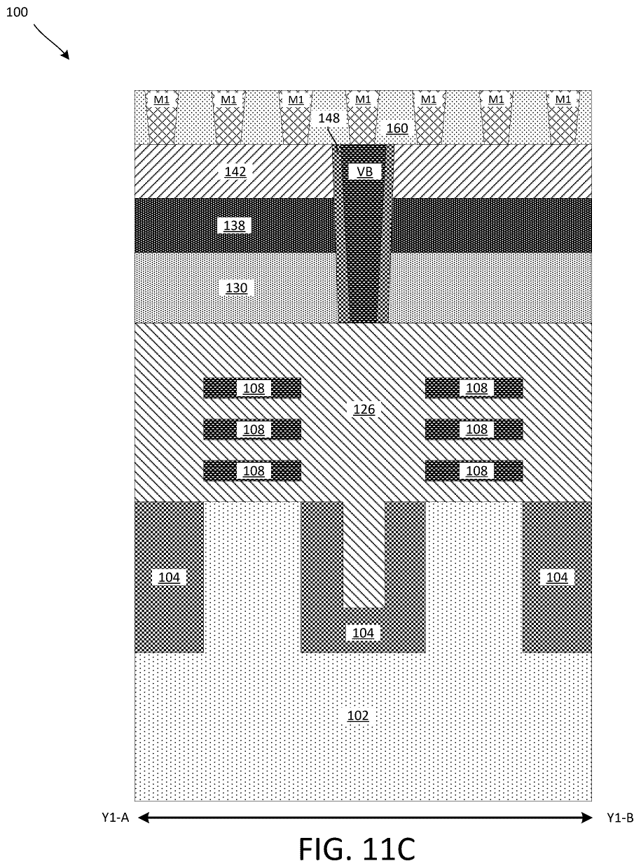

Referring now to FIG. 11A, this figure is a partial cross-sectional view of the semiconductor device 100 of FIG. 10A at a subsequent stage of the fabrication process and taken along the X1-A to X1-B line of FIG. 1B, according to embodiments. Similarly, FIG. 11B is a partial cross-sectional view of the semiconductor device 100 of FIG. 10B at a subsequent stage of the fabrication process and taken along the X2-A to X2-B line of FIG. 1B, and FIG. 11C is a partial cross-sectional view of the semiconductor device 100 of FIG. 10C at a subsequent stage of the fabrication process and taken along the Y1-A to Y1-B line of FIG. 1B. As shown in FIGS. 11A-11C, a fifth ILD layer 160 is formed on top of the fourth ILD layer 142. Then, M1 openings (not shown) are formed in the fifth ILD layer 160 by any suitable material removal process (e.g., RIE). Then metal layer contacts M1 are formed in these openings in the fifth ILD layer 160. In certain embodiments, the semiconductor device includes a back end of line (BEOL) layer and a middle of line (MOL) layer, wherein the gate contact VB is formed in the MOL layer.

As shown in FIG. 11B, because of the presence of the gate strap VB′ that creates an electrically conductive bridge connecting the center two HKMG stack structures 126, the rightmost gate contact VB (i.e., the one on the X2-B side of FIG. 11B) only needs to contact one of the two central HKMG stacks, rather than both of them. This results in an increased distance d1 in area al between the rightmost gate contact VB (i.e., on the X2-B side of FIG. 11B) and the leftmost metal layer contact M1 (i.e., on the X2-A side of FIG. 11B), which may decrease the risk of electrical shorting between these two components (i.e., as opposed to a case where the rightmost gate contact VB would be formed wider to connect to the top surfaces of both of the middle HKMG stack structures 126.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a substrate;
a shallow trench isolation (STI) layer formed on the substrate; and
a first gate, a second gate, and a gate strap connecting the first gate to the second gate, wherein the gate strap is formed in the STI layer.

2. The semiconductor device of claim 1, wherein a top surface of the gate strap is below a top surface of the STI layer.

3. The semiconductor device of claim 1, further comprising a first gate contact formed in contact with only the first gate.

4. The semiconductor device of claim 3, further comprising a sacrificial protective cap formed in contact with only the second gate.

5. The semiconductor device of claim 3, further comprising a source/drain epitaxial layer formed on the substrate.

6. The semiconductor device of claim 5, further comprising a source/drain contact formed on the source/drain epitaxial layer.

7. The semiconductor device of claim 6, wherein a top surface of the source/drain contact is below a top surface of the gate contact.

8. The semiconductor device of claim 6, further comprising a dielectric spacer layer formed around and in contact with the first gate contact, wherein the dielectric spacer layer is formed between the first gate contact and the source/drain contact to electrically isolate the first gate contact from the source/drain contact.

9. The semiconductor device of claim 8, wherein the dielectric spacer layer is also in contact with the source/drain contact.

10. The semiconductor device of claim 1, wherein the gate strap includes a high-k dielectric layer, a work function metal layer in contact with the high-K dielectric layer, and a gate metal fill layer in contact with the work function metal layer.

11. The semiconductor device of claim 3, further comprising a back end of line (BEOL) layer and a middle of line (MOL) layer, wherein the first gate contact is formed in the MOL layer.

12. The semiconductor device of claim 1, wherein the first gate and the second gate are formed as a nanosheet stack structure that includes alternating layers of a work function metal layer and a semiconductor layer.

13. The semiconductor device of claim 3, further comprising:
a third gate;
a second gate contact formed in contact with the third gate;
a first metal layer contacts formed in contact with the first gate contact; and
a second metal layer contact formed in contact with the second gate contact.

14. The semiconductor device according to claim 3, wherein the first gate contact is formed to a width so as to not cover the second gate.

15. An electronic device comprising:
a semiconductor device including:
a substrate;
a shallow trench isolation (STI) layer formed on the substrate; and
a first gate, a second gate, and a gate strap connecting the first gate to the second gate, wherein the gate strap is formed in the STI layer.

16. The electronic device of claim 15, wherein a top surface of the gate strap is below a top surface of the STI layer.

17. The electronic device of claim 15, further comprising a gate contact formed in contact with only the first gate.

18. The electronic device of claim 17, further comprising a sacrificial protective cap formed in contact with only the second gate.

19. The electronic device of claim 17, further comprising a source/drain epitaxial layer formed on the substrate.

20. The electronic device of claim 19, further comprising a source/drain contact formed on the source/drain epitaxial layer.
